(19) United States
(12) Patent Application Publication
(10) Pub. No.: US 2025/0376765 A1
(43) Pub. Date: Dec. 11, 2025

(54) FILM QUALITY IMPROVER, METHOD OF FORMING THIN FILM USING FILM QUALITY IMPROVER, SEMICONDUCTOR SUBSTRATE FABRICATED USING METHOD, AND SEMICONDUCTOR DEVICE INCLUDING SEMICONDUCTOR SUBSTRATE

(71) Applicant: SOULBRAIN CO., LTD., Gyeonggi-do (KR)

(72) Inventors: Chang Bong YEON, Gyeonggi-do (KR); Jae Sun JUNG, Gyeonggi-do (KR); Seung Hyun LEE, Gyeonggi-do (KR)

(21) Appl. No.: 19/281,863

(22) Filed: Jul. 28, 2025

Related U.S. Application Data
(62) Division of application No. 18/708,305, filed on May 8, 2024.

(30) Foreign Application Priority Data
Nov. 25, 2021 (KR) 10-2021-0164643
Aug. 22, 2022 (KR) 10-2022-0104489

(51) Int. Cl. C23C 16/455; C23C 16/44; H01L 21/285

(52) U.S. Cl. CPC C23C 16/45553; C23C 16/4408; H01L 21/28568

(57) ABSTRACT

The present invention relates to a film quality improver, a method of forming a thin film using the film quality improver, a semiconductor substrate fabricated using the method, and a semiconductor device including the semiconductor substrate. The present invention provides a compound having a predetermined structure as a film quality improver. According to the present invention, by forming a shielding area for a molybdenum-based thin film on a substrate, the deposition rate of a molybdenum-based thin film may be reduced, and the growth rate of a thin film may be controlled. Thus, even when forming a thin film using a solid compound on the substrate with a complicated structure at room temperature, step coverage and the thickness uniformity of the thin film may be greatly improved, and corrosion or deterioration may be prevented, thereby improving the crystallinity and electrical properties of a thin film.

This application is a Divisional Application of U.S. Ser. No. 18/708,305, filed on May 8, 2024, which is the National Stage Application of PCT/KR2022/017409, filed on Nov. 8, 2022, which claims priority to Korean Patent Application Nos. KR 10-2021-0164643, filed on Nov. 25, 2021, and KR 10-2022-0104489,filed on Aug. 22, 2022, all of which are incorporated by reference for all purposes as if fully set forth herein.

### TECHNICAL FIELD

The present invention relates to a film quality improver, a method of forming a thin film using the film quality improver, a semiconductor substrate fabricated using the method, and a semiconductor device including the semiconductor substrate. More particularly, the present invention relates to a film quality improver that is capable of reducing or increasing the deposition rate of a molybdenum-based thin film by forming a shielding area for a molybdenum-based thin film on a substrate and is capable of improving film quality such as step coverage, the thickness uniformity of a thin film, or resistivity when forming a thin film on a substrate with a complicated structure by appropriately controlling the growth rate of a thin film, or when forming a thin film using a solid precursor at room temperature, a method of forming a thin film using the film quality improver, and a semiconductor substrate fabricated using the method.

### BACKGROUND ART

Molybdenum (Mo) has excellent chemical and thermal stability, high electrical conductivity, and low electrical resistivity (ρ=0.57×10⁻⁵ Ω·cm at bulk). Accordingly, recently, molybdenum (Mo) has been in the spotlight as a material that meets requirements such as miniaturization of devices, low power consumption, and high productivity.

Specifically, molybdenum (Mo) is used in an electrode, a diffusion barrier, a gas sensor, and a catalyst material in various semiconductor and display metal processes. In particular, a molybdenum-containing thin film is receiving attention as a two-dimensional semiconductor material that can replace graphene materials, and research on application thereof is actively underway.

A representative molybdenum compound used to form a molybdenum-containing thin films is molybdenum chloride (MoCl₅). However, according to Thin Solid Films, 166, 149 (1988), molybdenum chloride has disadvantages such as low deposition rate, large chlorine content, and film contamination by hydrogen chloride. In particular, molybdenum chloride is a solid compound and has disadvantages such as particle contamination and the inability to vaporize a precursor uniformly.

In addition, Chem. Vap. Deposition (2008) 14, 71 has reported an imido compound such as Mo(NtBu)₂(NiPr₂)₂. However, the imido compound has relatively low thermal stability. In addition, due to the high stability caused by the π-bond between a molybdenum central metal and nitrogen due to an imido ligand, the ligand decomposition does not occur completely during a process, resulting in severe carbon contamination.

In US Patent Application Publication No. 4,431,708 and J. de Phys. IV 2 (C2), 865, a thin film containing molybdenum produced by vapor deposition using Mo(CO)₆ compound with relatively high vapor pressure is reported. The above compound is a solid compound at room temperature, so there is a high possibility of uneven vaporization characteristics, low thermal stability, and particle issues.

Therefore, there is a need for development of a method of forming a thin film that allows the formation of a thin film with a complicated structure even when a compound is in solid form at room temperature without containing halogens, which are highly likely to cause adverse effects on semiconductor and display devices, in a thin film, and greatly improves step coverage and the thickness uniformity of the thin film; and a semiconductor substrate fabricated using the method.

### DISCLOSURE

### Technical Problem

Therefore, the present invention has been made in view of the above problems, and it is one object of the present invention to provide a film quality improver that is capable of reducing or increasing the deposition rate of a molybdenum-based thin film by forming a shielding area for a molybdenum-based thin film on a substrate and is capable of improving film quality such as step coverage, the thickness uniformity of a thin film, or resistivity when forming a thin film on a substrate with a complicated structure by appropriately controlling the growth rate of a thin film, or when forming a thin film using a solid precursor at room temperature, a method of forming a thin film using the film quality improver, and a semiconductor substrate fabricated using the method.

It is another object of the present invention to improve the density and electrical properties of a thin film by improving the crystallinity of the thin film.

The above and other objects can be accomplished by the present invention described below.

### Technical Solution

In accordance with one aspect of the present invention, provided is a film quality improver for a molybdenum-based thin film,
wherein the molybdenum-based thin film includes molybdenum, molybdenum oxide, or molybdenum nitride on a substrate, and
the film quality improver is a saturated compound represented by Chemical Formula 1 below.

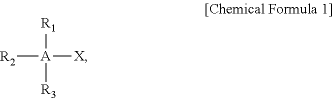

wherein A is carbon (C) or silicon (Si); X is fluorine (F), chlorine (Cl), bromine (Br), or iodine (I);
R₁ and R₃ are independently hydrogen, an alkyl group having 1 to 5 carbon atoms, fluorine (F), chlorine (Cl), bromine (Br), or iodine (I);
R₂ independently has hydrogen, an alkyl group having 1 to 5 carbon atoms, fluorine (F), chlorine (Cl), bromine (Br), iodine (I), or a functional group of formula BR₄R₅R₆; B is carbon or silicon; and R₄, R₅, and R₆ are independently hydrogen, an alkyl group having 1 to 5 carbon atoms, fluorine (F), chlorine (Cl), bromine (Br), or iodine (I).

The film quality improver may have a refractive index (a) of 1.38 to 1.72, and a value (b/a) obtained by dividing vapor pressure (25° C., mmHg, b) by the refractive index (a) may be 0.003 to 0.043.

When comparing ¹H-NMR spectrum for the film quality improver and ¹H-NMR spectrum measured after mixing the film quality improver and a molybdenum precursor in a molar ratio of 1:1 and pressing, the film quality improver may be a compound in which an integral value of a newly created peak is less than 0.1%.

The molybdenum precursor may be solid or liquid under conditions of 20° C. and 1 bar.

The film quality improver may provide a shielding area for a molybdenum-based thin film.

The shielding area for a molybdenum-based thin film may be formed on a substrate on which the molybdenum-based thin film is formed.

The shielding area for a molybdenum-based thin film may not remain on the molybdenum-based thin film, and the molybdenum-based thin film may include carbon, silicon, and a halogen compound in an amount of 1% or less.

The molybdenum-based thin film may be used as a diffusion barrier or an electrode.

In accordance with another aspect of the present invention, provided is a method of forming a molybdenum-based thin film, the method including injecting a film quality improver with a saturated structure represented by Chemical Formula 1 below into a chamber and injecting the film quality improver onto a surface of a loaded substate.

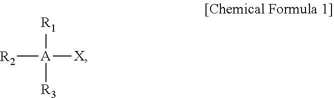

wherein A is carbon (C) or silicon (Si); X is fluorine (F), chlorine (Cl), bromine (Br), or iodine (I); R₁ and R₃ are independently hydrogen, an alkyl group having 1 to 5 carbon atoms, fluorine (F), chlorine (Cl), bromine (Br), or iodine (I); R₂ independently has hydrogen, an alkyl group having 1 to 5 carbon atoms, fluorine (F), chlorine (Cl), bromine (Br), iodine (I), or a functional group of formula BR₄R₅R₆; B is carbon or silicon; and R₄, R₅, and R₆ are independently hydrogen, an alkyl group having 1 to 5 carbon atoms, fluorine (F), chlorine (Cl), bromine (Br), or iodine (I).

The method of forming a molybdenum-based thin film may include step i-a) of vaporizing the film quality improver to form a shielding area on a surface of a substrate loaded into a chamber; step ii-a) of performing first purging of an inside of the chamber using a purge gas; step iii-a) of vaporizing a molybdenum precursor and adsorbing the molybdenum precursor to an area outside the shielding area; step iv-a) of performing second purging of the inside of the chamber using a purge gas; step v-a) of supplying a reaction gas into the chamber; and step vi-a) of performing third purging of the inside of the chamber using a purge gas.

In addition, the method of forming a molybdenum-based thin film may include step i-b) of vaporizing a molybdenum precursor and adsorbing the molybdenum precursor on a surface of a substrate loaded into the chamber, step ii-b) of performing first purging of an inside of the chamber using a purge gas; step iii-b) of vaporizing the film quality improver and injecting the film quality improver onto the surface of the substrate loaded into the chamber; step iv-b) of performing second purging of the inside of the chamber using a purge gas; step v-b) of supplying a reaction gas into the chamber; and step vi-b) of performing third purging of the inside of the chamber using a purge gas.

The molybdenum precursor may be solid or liquid under conditions of 20° C. and 1 bar, and may be a molybdenum precursor with a vapor pressure of 0.1 mTorr to 100 10 Torr at 30° C.

The molybdenum precursor may include one or more selected from compounds represented by Chemical Formulas 2 to 36 below.

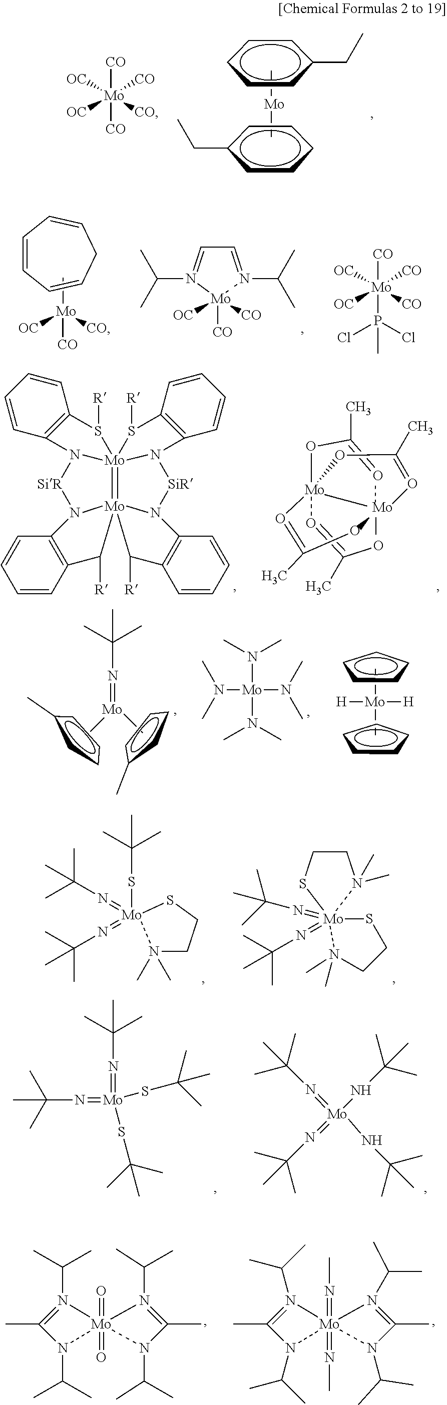

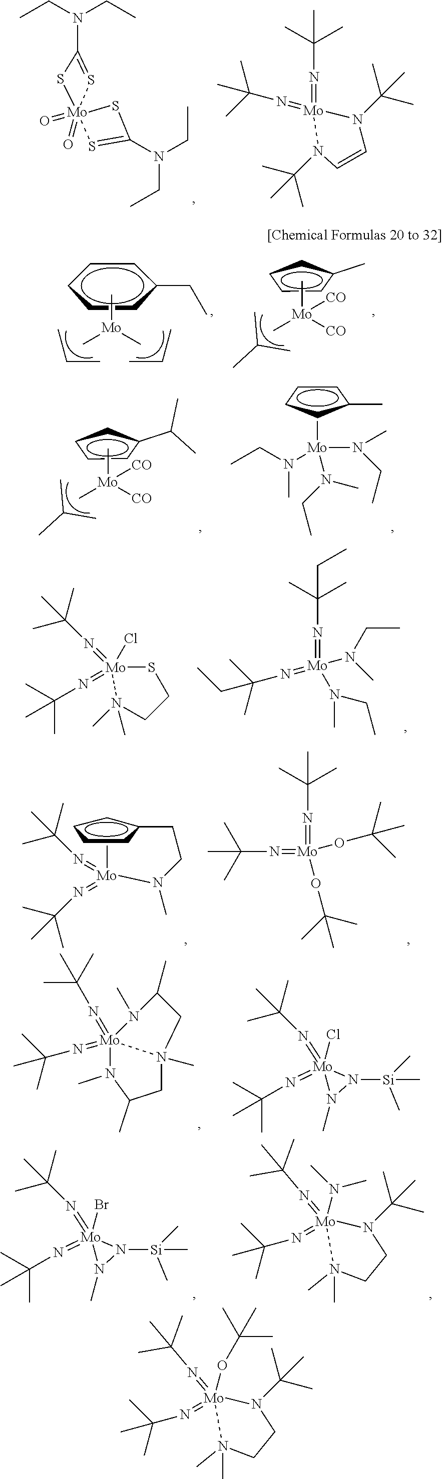

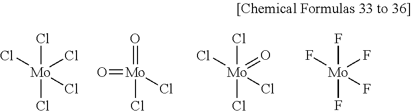

In Chemical Formulas 2 to 36, a lines represents a bond; carbon is located at a point where bonds meet without specifying a separate element; a hydrogen number that satisfies a valence of the carbon is omitted; R′and R″ are cach hydrogen or an alkyl group having 1 to 5 carbon atoms; and R′ is connected to adjacent R′.

The chamber may be an ALD chamber or a CVD chamber.

The method may include vaporizing and injecting the film quality improver or the molybdenum precursor and then performing plasma post-processing.

An amount of the purge gas injected into the chamber in steps ii) and step iv) may be 10 to 100,000 times a volume of the injected film quality improver.

The reaction gas, the film quality improver, and the molybdenum precursor may be transferred into the chamber by a VFC method, a DLI method, or an LDS method.

The substrate into the chamber may be heated to 50 to 400° C., and the input ratio (mg/cycle) of the film quality improver and molybdenum precursor introduced into the chamber may be 1:1.5 to 1:20.

The reaction gas may be a reducing agent, a nitriding agent, or an oxidizing agent.

In the method of forming a molybdenum-based thin film, deposition temperature may be 50 to 700° C.

The molybdenum-based thin film may be an oxide film, a nitride film, or a metal film.

In accordance with still another aspect of the present invention, provided is a semiconductor substrate fabricated using the method of forming a molybdenum-based thin film.

The molybdenum-based thin film may have a multilayer structure consisting of two or three layers.

In accordance with yet another aspect of the present invention, provided is a semiconductor device including the semiconductor substrate.

The semiconductor substrate may be low resistive metal gate interconnects, a high aspect ratio 3D metal-insulator-metal (MIM) capacitor, a DRAM trench capacitor, 3D Gate-All-Around (GAA), or 3D NAND.

### Advantageous Effects

According to the present invention, by forming a shielding area for a molybdenum-based thin film on a substrate, the deposition rate of a molybdenum-based thin film can be reduced, and the growth rate of a thin film can be controlled. Thus, even when forming a thin film using a solid compound on the substrate with a complicated structure at room temperature, a film quality improver capable of improving step coverage can be provided.

In addition, process by-products are more effectively reduced when forming a thin film, preventing corrosion or deterioration and improving the crystallinity of the thin film, thereby improving the electrical properties of the thin film.

In addition, when forming a thin film, process by-products are reduced and step coverage and thin film density can be improved. Furthermore, the present invention has the effect of providing a method of forming a thin film using the film quality improver and a semiconductor substrate fabricated using the method.

### DESCRIPTION OF DRAWINGS

FIG. 1 is a diagram comparing the results of Example 6 of an experiment in which the film quality improver suggested in the present invention was pre-injected and post-injected into MoO₂Cl₂ and an experiment in which the film quality improver was not used. In FIG. 1, the left graph shows the resistivity measurement results, and the right graph shows the deposition rate measurement results.

### BEST MODE

Hereinafter, a film quality improver for a molybdenum-based thin film of the present invention, a method of forming a molybdenum-based thin film using the film quality improver, and a semiconductor substrate fabricated using the method are described in detail.

In this description, unless otherwise specified, the term “shielding” means reducing, preventing, or blocking the adsorption of a molybdenum precursor for forming a molybdenum-based thin film on a substrate. Additionally, “shielding” means reducing, preventing, or blocking the adsorption of process by-products onto the substrate.

The present inventors confirmed that, when a film quality improver that shields a molybdenum precursor for forming a molybdenum-based thin film on the surface of a substrate loaded into a chamber was used, a relatively sparse thin film was formed by forming a shielding area that did not remain in the molybdenum-based thin film. At the same time, by adjusting the growth rate of the formed thin film, uniformity of the thin film was secured even when applied to a substrate with a complicated structure, and step coverage was greatly improved. In particular, thin-thickness deposition was possible, and the amount of residual carbon, which was difficult to reduce even with the use of halide and excessive hydrogen gas remaining as process by-products, was improved. Based on these results, the present inventors conducted research on a film quality improver that provides a shielding area to complete the present invention.

The present invention provides a film quality improver for a molybdenum-based thin film.

For example, the molybdenum-based thin film may be provided as one or more precursors selected from compounds represented by Chemical Formulas 2 to 36 below. In this case, the effect desired to be achieved in the present invention may be fully achieved.

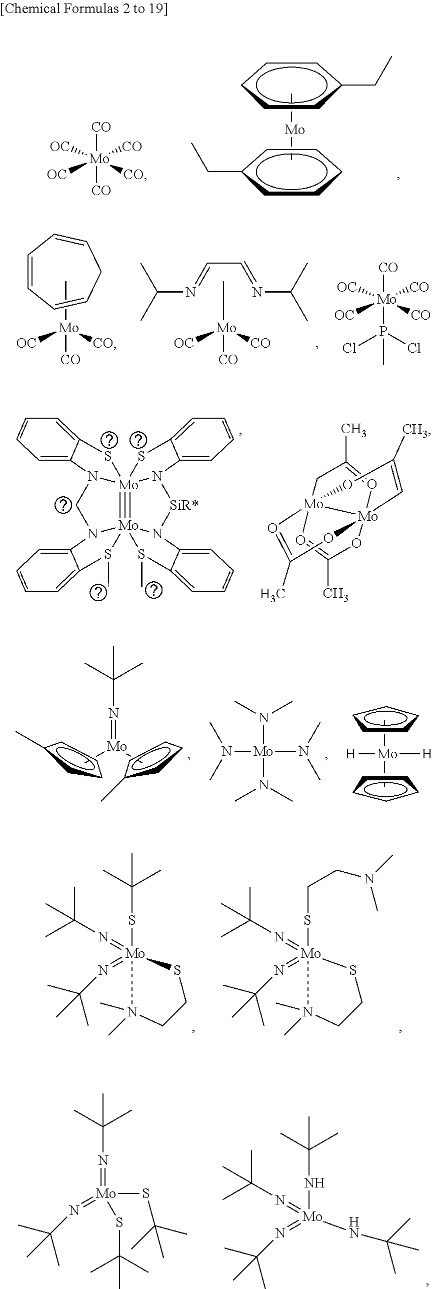

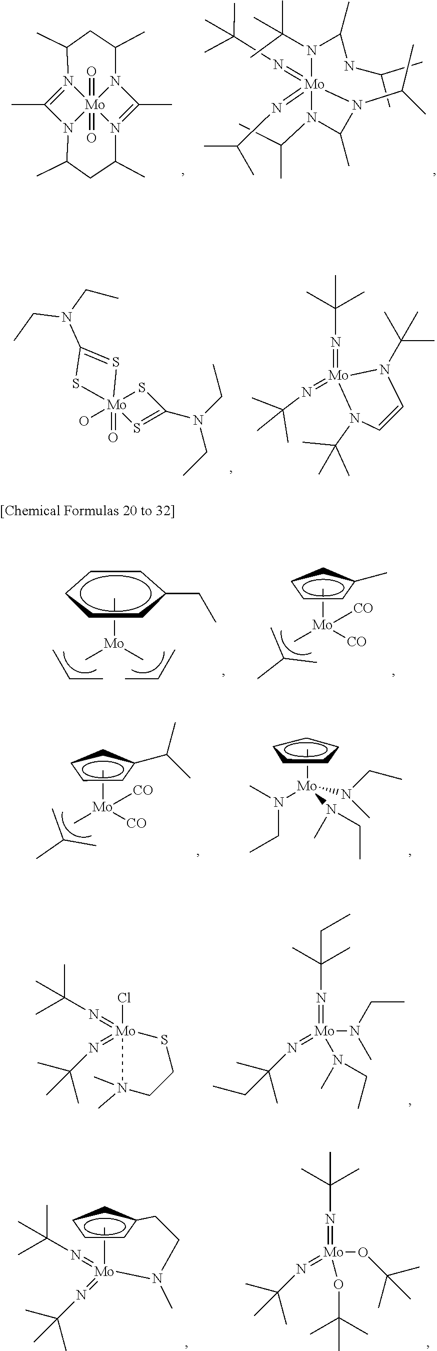

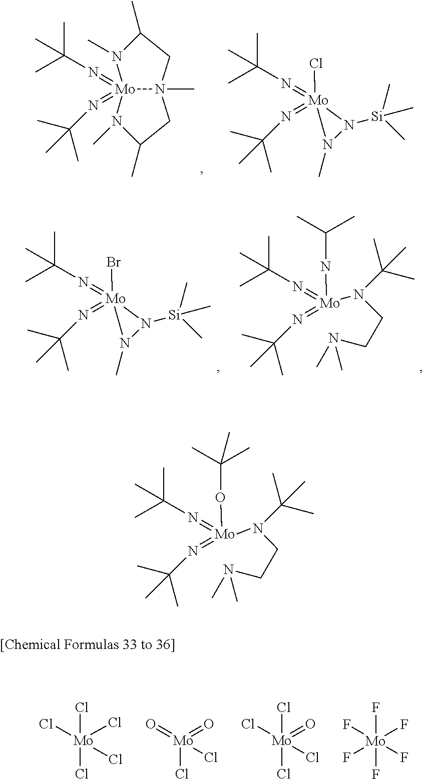

In Chemical Formulas 2 to 36, a lines represents a bond; carbon is located at a point where bonds meet without specifying a separate element; a hydrogen number that satisfies the valence of the carbon is omitted; R′ and R″ are each hydrogen or an alkyl group having 1 to 5 carbon atoms; and R′ is connected to adjacent R′.

In addition to a commonly used diffusion barrier, the molybdenum-based thin film may be used as an electrode in semiconductor devices.

The film quality improver is a saturated compound represented by Chemical Formula 1 below.

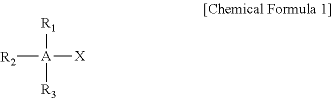

In Chemical Formula 1, A is carbon (C) or silicon (Si); X is fluorine (F), chlorine (Cl), bromine (Br), or iodine (I); R₁ and R₃ are independently hydrogen, an alkyl group having 1 to 5 carbon atoms, fluorine (F), chlorine (Cl), bromine (Br), or iodine (I); R₂ independently has hydrogen, an alkyl group having 1 to 5 carbon atoms, fluorine (F), chlorine (Cl), bromine (Br), iodine (I), or a functional group of formula BR₄R₅R₆; B is carbon or silicon; and R₄, R₅, and R₆ are independently hydrogen, an alkyl group having 1 to 5 carbon atoms, fluorine (F), chlorine (Cl), bromine (Br), or iodine (I). In this case, when forming a molybdenum-based thin film, a shielding area that does not remain in the molybdenum-based thin film is formed. Thus, a relatively sparse thin film may be formed. In addition, by suppressing side reactions and controlling the growth rate of a thin film, process by-products within the thin film may be reduced, thereby preventing corrosion and deterioration and improving crystallinity of the thin film. In addition, even when a thin film is formed on a substrate having a complicated structure, step coverage and the thickness uniformity of the thin film may be greatly improved.

In Chemical Formula 1, A is carbon or silicon, preferably carbon.

R₁, R₂, and R₃ are each independently alkyl groups having 1 to 3 carbon atoms, and one or more of R₁, R₂, and R₃ has 2 or 3 carbon atoms. As a preferred example, one or more of R₁, R₂, and R₃ has 1 carbon atom and the remaining two have 2 or 3 carbon atoms. More preferably, any one of R₁, R₂, and R₃ has 1 carbon atom and the remaining two has 2 carbon atoms. Within this range, process by-products may be greatly reduced, step coverage may be excellent, and the density and electrical properties of a thin film may be improved.

In Chemical Formula 1, X may be a halogen element, preferably fluorine, chlorine, or bromine, more preferably chlorine or bromine. Within this range, process by-products may be reduced and step coverage may be improved. In addition, X may be fluorine. This case may be more suitable for processes requiring high temperature deposition.

In Chemical Formula 1, as a preferred example, X may be iodine. Within this range, thin film crystallinity may be improved, and side reactions may be suppressed, thereby reducing process by-products.

The compound represented by Chemical Formula 1 may be a halogen-substituted tertiary alkyl compound. As a specific example, the compound may include one or more selected from the group consisting of 2-chloro-2-methylpropane, 2-chloro-2methylbutane, 2-chloro-2-methylpentane, 3-chloro-3-methylpentane, 3-chloro-3-methylhexane, 3-chloro-3-ethylpentane, 3-chloro-3-ethylhexane, 4-chloro-4-methylheptane, 4-chloro-4-ethylheptane, 4-chloro-4-propylheptane, 2-bromo-2-methylpropane, 2-bromo-2-methylbutane, 2-bromo-2-methylpentane, 3-bromo-3-methylpentane, 3-bromo-3-methylhexane, 3-bromo-3-ethylpentane, 3-bromo-3-ethylhexane, 4-bromo-4-methylheptane, 4-bromo-4-ethylheptane, 4-bromo-4-propylheptane, 2-iodo-2-methylpropane, 2-iodo-2-methylbutane, 2-iodo-2-methylpentane, 3-iodo-3-methylpentane, 3-iodo-3-methylhexane, 3-iodo-3-ethylpentane, 3-iodo-3-ethylhexane, 4-iodo-4-methylheptane, 4-iodo-4-ethylheptane, 4-iodo-4-propylheptane, 2-fluoro-2-methylpropane, 2-fluoro-2-methylbutane, 2-fluoro-2-methylpentane, 3-fluoro-3-methylpentane, 3-fluoro-3-methylhexane, 3-fluoro-3-ethylpentane, 3-fluoro-3-ethylhexane, 4-fluoro-4-methylheptane, 4-fluoro-4-ethylheptane, and 4-fluoro-4-propylheptane, preferably one or more selected from the group consisting of 2-chloro-2-methylpropane, 2-chloro-2-methylbutane, 3-chloro-3-methylpentane, 2-bromo-2-methylpropane, 2-bromo-2-methylbutane, 3-bromo-3-methylpentane, 2-iodo-2-methylpropane, 2-iodo-2-methylbutane, 3-iodo-3-methylpentane, 2-fluoro-2-methyl propane, 2-fluoro-2-methylbutane, and 3-fluoro-3-methylpentane. In this case, the effect of controlling the growth rate of a thin film may be achieved by providing a shielding area for molybdenum thin films. Additionally, process by-products may be effectively removed, and step coverage and film quality may be improved.

For example, the compound represented by Chemical Formula 1 may be a saturated compound having a refractive index (a) of 1.38 to 1.72. For the compound, a value (b/a) obtained by dividing vapor pressure (mmHg, b) measured at 25° C. by the refractive index (a) may be 0.003 to 0.043. In this case, by forming a shielding area for a molybdenum-based thin film on a substrate, the deposition rate of a molybdenum-based thin film may be reduced, and the growth rate of a thin film may be controlled. Thus, even when forming a thin film on the substrate with a complicated structure, step coverage and the thickness uniformity of the thin film may be greatly improved. In addition to the thin film precursor, the adsorption of process by-products may be inhibited, thereby effectively protecting the surface of the substrate and effectively eliminating process by-products.

In the present invention, the refractive index may be measured by methods known in the art unless otherwise specified. As a specific example, the refractive index may be measured at 25° C. using an Abbe refractometer according to ASTM D542.

As a specific example, the compound represented by Chemical Formula 1 may be a saturated compound having a refractive index (a) of 1.385 to 1.72. For the compound, a value (b/a) obtained by dividing vapor pressure (mmHg, b) measured at 25° C. by the refractive index (a) may be 0.032 to 0.043. Preferably, the compound represented by Chemical Formula 1 may be a saturated compound having a refractive index (a) of 1.388 to 1.719. For the compound, a value (b/a) obtained by dividing vapor pressure (mmHg, b) measured at 25° C. by the refractive index (a) may be 0.0035 to 0.043. In this case, by forming a shielding area for a molybdenum-based thin film on a substrate, the deposition rate of a molybdenum-based thin film may be reduced, and the growth rate of a thin film may be controlled. Thus, even when forming a thin film on the substrate with a complicated structure, step coverage and the thickness uniformity of the thin film may be greatly improved. In addition to the thin film precursor, the adsorption of process by-products may be inhibited, thereby effectively protecting the surface of the substrate and effectively eliminating process by-products.

Regarding the reactivity of the film quality improver and the molybdenum precursor, when the integral value of the NMR peak generated by comparing the H-NMR spectrum measured before mixing the film quality improver and the molybdenum precursor and the H-NMR spectrum measured after pressing the mixture at a molar ratio of 1:1 for 1 hour is referred to as impurities content, the impurities content (%) is less than 0.1%. Thus, when the film quality improver is used, process by-products may be reduced without interfering with adsorption of the molybdenum precursor, the deposition rate may be controlled, and the growth rate of a thin film may be controlled. Thus, when forming a thin film on a substrate with a complicated structure, step coverage and film quality may be improved, corrosion or deterioration may be prevented, the crystallinity of a thin film may be improved, thereby improving the resistivity properties and electrical properties of the thin film.

Due to the above-mentioned reactivity, the film quality improver has the advantage of easily controlling the viscosity or vapor pressure of the molybdenum precursor but not interfering with the behavior of the molybdenum precursor.

For example, the film quality improver that exhibits this reactivity may be a halogen-substituted straight-chain or branched-chain alkane compound or cycloalkane compound.

As a specific example, the film quality improver may include one or more selected from the group consisting of 1-iodobutane, 2-iodobutane, 2-iodo-3-methyl butane, 3-iodo-2,4-dimethyl pentane, cyclohexyl iodide, cyclopentyl iodide, 1-bromobutane, 2-bromobutane, 2-bromo-3-methyl butane, 3-bromo-2,4-dimethyl pentane, cyclohexyl bromide, and cyclopentyl bromide, preferably one or more selected from the group consisting of 1-iodobutane and 2-iodobutane. In this case, the compound may effectively protect the surface of a substrate by acting as a film quality improver without interfering with adsorption of the molybdenum precursor, and process by-products may be effectively removed.

The film quality improver does not remain in the molybdenum-based thin film.

At this time, unless otherwise specified, “not remaining” means that the C, Si, N, and halogen elements each exist in an amount of less than 1.0 atom % when analyzing ingredients using XPS.

The molybdenum-based thin film may be used as a diffusion barrier or an electrode, but the present invention is not limited thereto.

The film quality improver may be preferably a compound with a purity of 99.9% or higher, a compound with a purity of 99.95% or higher, or a compound with a purity of 99.99% or higher. For reference, when a compound with a purity of less than 99% is used, impurities may form, so it is preferable to use a substance with a purity of 99% or higher.

The compound represented by Chemical Formula 1 is preferably used in an atomic layer deposition (ALD) process. In this case, the compound may effectively protect the surface of a substrate by acting as a film quality improver without interfering with adsorption of the molybdenum precursor, and process by-products may be effectively removed.

Preferably, the compound represented by Chemical Formula 1 may be in a liquid state at room temperature (22° C.) and may have a density of 0.8 to 2.5 g/cm³ or 0.8 to 1.5 g/cm³, a vapor pressure (20° C.) of 0.1 to 300 mmHg or 1 to 300 mmHg, and a solubility (25° C.) of 200 mg/L or less in water. Within this range, a shielding area may be effectively formed, and step coverage, the thickness uniformity of a thin film, and film quality may be excellent.

More preferably, the compound represented by Chemical Formula 1 may have a density of 0.75 to 2.0 g/cm³ or 0.8 to 1.3 g/cm³, a vapor pressure (20° C.) of 1 to 260 mmHg, and a solubility (25° C.) of 160 mg/L or less in water. Within this range, a shielding area may be effectively formed, and step coverage, the thickness uniformity of a thin film, and film quality may be excellent.

The method of forming a molybdenum-based thin film of the present invention includes a step of injecting a film quality improver represented by Chemical Formula 1 below into an ALD chamber and adsorbing the film quality improver onto a substrate loaded into the chamber.

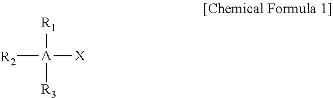

In Chemical Formula 1, A is carbon (C) or silicon (Si); X is fluorine (F), chlorine (Cl), bromine (Br), or iodine (I); R₁ and R₃ are independently hydrogen, an alkyl group having 1 to 5 carbon atoms, fluorine (F), chlorine (Cl), bromine (Br), or iodine (I); R₂ independently has hydrogen, an alkyl group having 1 to 5 carbon atoms, fluorine (F), chlorine (Cl), bromine (Br), iodine (I), or a functional group of formula BR₄R₅R₆; B is carbon or silicon; and R₄, R₅, and R₆ are independently hydrogen, an alkyl group having 1 to 5 carbon atoms, fluorine (F), chlorine (Cl), bromine (Br), or iodine (I). In this case, by forming a shielding area for a molybdenum-based thin film on a substrate, the deposition rate of a molybdenum-based thin film may be reduced, and the growth rate of a thin film may be controlled. Thus, even when forming a thin film on the substrate with a complicated structure, step coverage and the thickness uniformity of the thin film may be greatly improved. In addition, the effect of improving film quality, such as improving resistivity, may be achieved.

In the step of shielding the film quality improver on the surface of a substrate, when the film quality improver is fed onto the surface of the substate, the feeding time per cycle may be preferably 0.01 to 5 seconds, more preferably 0.02 to 3 seconds, still more preferably 0.04 to 2 seconds, still more preferably 0.05 to 1 second. Within this range, the growth rate of a thin film may be reduced, and step coverage and economics may be excellent.

In the present disclosure, the feeding time of the film quality improver is determined based on a chamber volume of 15 to 20 L and a flow rate of 0.5 to 5 mg/s, more specifically, based on a chamber volume of 18 L and a flow rate of 1 to 2 mg/s.

As a preferred example, the method of forming a thin film may include step i-a) of vaporizing the film quality improver and shielding the film quality improver on the surface of a substrate loaded into an ALD chamber; step ii-a) of performing first purging of the inside of the ALD chamber using a purge gas; step iii-a) of vaporizing a molybdenum precursor and adsorbing the molybdenum precursor on the surface of the substrate loaded into the chamber; step iv-a) of performing second purging of the inside of the chamber using a purge gas; step v-a) of supplying a reaction gas into the ALD chamber; and step via) of performing third purging of the inside of the chamber using a purge gas. At this time, when setting steps i-a) to vi-a) as a unit cycle, the unit cycle may be repeated until a thin film of a desired thickness is obtained. In this way, within one cycle, when the film quality improver of the present invention is added before the molybdenum precursor and adsorbed to the substrate, even when deposited at high temperature, the growth rate of a thin film may be appropriately reduced. In addition, generated process by-products may be effectively eliminated, thereby reducing the resistivity of the thin film and greatly improving step coverage.

As another example, the method of forming a thin film may include step i-b) of vaporizing a molybdenum precursor and adsorbing the molybdenum precursor on the surface of a substrate loaded into a chamber; step ii-b) of performing first purging of the inside of the chamber using a purge gas; step iii-b) of vaporizing the film quality improver and adsorbing the film quality improver on the surface of the substrate loaded into the chamber; step iv-b) of performing second purging of the inside of the ALD chamber using a purge gas; step v-b) of supplying a reaction gas into the chamber; and step vi-b) of performing third purging of the inside of the chamber using a purge gas. At this time, when setting steps i-b) to vi-b) as a unit cycle, the unit cycle may be repeated until a thin film of a desired thickness is obtained. In this way, within one cycle, when the film quality improver of the present invention is added after the molybdenum precursor and adsorbed to the substrate, the film quality improver may act as a growth activator for thin film formation. In this case, the growth rate of a thin film may be increased. In addition, the density and crystallinity of the thin film may be increased, thereby reducing the resistivity of the thin film and greatly improving electrical properties.

As a preferred example, according to the method of forming a thin film of the present invention, within one cycle, the film quality improver of the present invention may be supplied before the molybdenum precursor and adsorbed to the substrate. In this case, even when the thin film is deposited at high temperatures, the growth rate of the thin film may be appropriately reduced, thereby greatly reducing process by-products and greatly improving step coverage. In addition, the crystallinity of the thin film may be increased, thereby reducing the resistivity of the thin film. In addition, even when the thin film is applied to a semiconductor device with a large aspect ratio, since the thickness uniformity of the thin film is greatly improved, the reliability of the semiconductor device may be secured.

For example, according to the method of forming a thin film, when depositing the film quality improver before or after deposition of the molybdenum precursor, when necessary, the unit cycle may be repeated 1 to 99,999 times, preferably 10 to 10,000 times, more preferably 50 to 5,000 times, still more preferably 100 to 2,000 times. Within this range, a thin film having a desired thickness may be obtained, and the effects desired to be achieved in the present invention may be fully achieved.

For example, in the present invention, the chamber may be an ALD chamber or a CVD chamber.

The method of the present invention may include a step of vaporizing and injecting the film quality improver or molybdenum precursor and performing plasma post-processing. In this case, thin film growth rate may be improved, and process by-products may be reduced.

When the film quality improver is first adsorbed onto the substrate and then the molybdenum precursor is adsorbed, or when the molybdenum precursor is first adsorbed and then the film quality improver is adsorbed, in the step of purging the non-adsorbed film quality improver, an amount of the purge gas introduced into the chamber is not particularly limited as long as the amount is sufficient to remove the non-adsorbed film quality improver. For example, the amount of the purge gas may be 10 to 100,000 times, preferably 50 to 50,000 times, more preferably 100 to 10,000 times. Within this range, the non-adsorbed film quality improver is sufficiently removed so that a thin film may be formed evenly and deterioration of film quality may be prevented. Here, the input amounts of the purge gas and film quality improver are each based on one cycle, and the volume of the film quality improver refers to the volume of the vaporized film quality improver.

As a specific example, the film quality improver may be injected (per cycle) at a flow rate of 1.66 mL/s and an injection time of 0.5 sec. In the step of purging the non-adsorbed film quality improver, when the purge gas is injected (per cycle) at a flow rate of 166.6 mL/s and an injection time of 3 sec, the injection amount of the purge gas is 602 times that of the film quality improver.

In addition, in the step of purging the non-adsorbed molybdenum precursor, an amount of the purge gas introduced into the ALD chamber is not particularly limited as long as the amount is sufficient to remove the non-adsorbed molybdenum precursor. For example, based on the volume of the molybdenum precursor introduced into the ALD chamber, the amount of the purge gas may be 10 to 10,000 times, preferably 50 to 50,000 times, more preferably 100 to 10,000 times. Within this range, the non-adsorbed molybdenum precursor is sufficiently removed so that a thin film may be formed evenly and deterioration of film quality may be prevented. Here, the input amounts of the purge gas and molybdenum precursor are each based on one cycle, and the volume of the molybdenum precursor refers to the volume of the vaporized molybdenum precursor.

In addition, in the purging step performed immediately after the reaction gas supply step, based on the volume of the reaction gas introduced into the ALD chamber, the amount of the purge gas introduced into the ALD chamber may be 10 to 10,000 times, preferably 50 to 50,000 times, more preferably 100 to 10,000 times. Within this range, the desired effect may be sufficiently obtained. Here, the input amounts of the purge gas and reaction gas are each based on one cycle.

The film quality improver and the molybdenum precursor may preferably be transferred into an ALD chamber by a VFC method, a DLI method, or an LDS method, more preferably an LDS method.

For example, the substate loaded into the chamber may be heated to 50 to 700° C., as a specific example, 300 to 700° C. The film quality improver or molybdenum precursor may be injected onto the substrate with or without heating. Depending on the deposition efficiency, the heating conditions may be adjusted during the deposition process after injection without heating. For example, the film quality improver or molybdenum precursor may be injected onto the substrate at 50 to 700° C. for 1 to 20 seconds.

When the film quality improver and the molybdenum precursor are fed into ALD chamber, the input amount ratio (mg/cycle) of the film quality improver to the molybdenum precursor may be preferably 1:1.5 to 1:20, more preferably 1:2 to 1:15, still more preferably 1:2 to 1:12, still more preferably 1:2.5 to 1:10. Within this range, step coverage may be improved, and process by-products may be reduced.

For example, the molybdenum precursor may be fed into a chamber after being mixed with a non-polar solvent. In this case, the viscosity of the molybdenum precursor or vapor pressure may be easily adjusted.

The non-polar solvent may include preferably one or more selected from the group consisting of alkanes and cycloalkanes. In this case, step coverage may be improved even when deposition temperature is increased when forming a thin film while containing an organic solvent having low reactivity and solubility and capable of easy moisture management.

As a more preferred example, the non-polar solvent may include a C1 to C10 alkane or a C3 to C10 cycloalkane, preferably a C3 to C10 cycloalkane. In this case, reactivity and solubility may be reduced, and moisture management may be easy.

In the present disclosure, C1, C3, and the like mean the carbon number.

The cycloalkane may be preferably a C3 to C10 monocycloalkane. Among the monocycloalkanes, cyclopentane exists in a liquid state at room temperature and has the highest vapor pressure, and thus is preferable in a vapor deposition process. However, the present invention is not limited thereto.

For example, the non-polar solvent has a solubility (25° C.) of 200 mg/L or less, preferably 50 to 400 mg/L, more preferably 135 to 175 mg/L in water. Within this range, reactivity to the molybdenum precursor may be low, and moisture management may be easy.

In the present disclosure, solubility may be measured without particular limitation according to measurement methods or standards commonly used in the art to which the present invention pertains. For example, solubility may be measured according to the HPLC method using a saturated solution.

Based on a total weight of the molybdenum precursor and the non-polar solvent, the non-polar solvent may be included in an amount of preferably 5 to 95% by weight, more preferably 10 to 90% by weight, still more preferably 40 to 90% by weight, most preferably 70 to 90% by weight.

When the content of the non-polar solvent exceeds the above range, impurities are generated to increase resistance and impurity levels in a thin film. When the content of the non-polar solvent is less than the above range, an effect of improving step coverage and reducing impurities such as chlorine (Cl) ions due to addition of the solvent may be reduced.

For example, in the method of forming a molybdenum-based thin film, when the film quality improver is used, the reduction rate of thin film growth rate per cycle (Å/Cycle) calculated by Equation 1 below is −5% or less, preferably −10% or less, more preferably −20% or less, still more preferably −30% or less, still more preferably −40% or less, most preferably −45% or less. Within this range, step coverage and the thickness uniformity of the film may be excellent.

$$Reduction rate of thin film growth rate per cylce ( \% ) = [ ( Thin film growth rate per cycle when film quality improviser is used - Thin film growth rate per cycle when film quality improviser is not used ) / Thin film growth rate per cycle when film quality improviser is not used ] \times 100 \qquad [ Equation 1 ]$$

In Equation 1, the thin film growth rate per cycle when using and not using the film quality improver refers to the thin film deposition thickness per cycle (Å/cycle), that is, the deposition rate. For example, when measuring the deposition rate, the final thickness of the thin film may be measured by ellipsometry, and the average deposition rate may be obtained by dividing the measured value by the total number of cycles.

In Equation 1, “when the film quality improver is not used” refers to a case where a thin film is formed by adsorbing only the molybdenum precursor onto the substrate in the thin film deposition process. As a specific example, in the method of forming a thin film, “when the film quality improver is not used” refers to a case where a thin film is formed by omitting the step of adsorbing the film quality improver and the step of purging the non-adsorbed film quality improver.

In the method of forming a molybdenum-based thin film, based on a thin film thickness of 100 Å measured by SIMS, residual halogen intensity (c/s) in a thin film may be preferably 100,000 or less, more preferably 70,000 or less, still more preferably 50,000 or less, still more preferably 10,000 or less, as a preferred example, 5,000 or less, more preferably 1,000 to 4,000, still more preferably 1,000 to 3,800. Within this range, corrosion and deterioration may be prevented.

In the present disclosure, purging may be performed preferably at 1,000 to 50,000 sccm (Standard Cubic Centimeter per Minute), more preferably 2,000 to 30,000 sccm, still more preferably 2,500 to 15,000 sccm. Within this range, thin film growth rate per cycle may be appropriately controlled. In addition, an atomic mono-layer or a similar type of layer may be formed through deposition, which is advantageous in terms of film quality.

The atomic layer deposition (ALD) process is very advantageous in fabricating integrated circuits (ICs) requiring a high aspect ratio, and in particular, due to a self-limiting thin film growth mechanism, excellent conformality and uniformity and precise thickness control may be achieved.

For example, in the method of forming a thin film, the deposition temperature may be 50 to 800° C., preferably 300 to 700° C., more preferably 350 to 650° C. Within this range, an effect of growing a thin film having excellent film quality may be obtained while implementing ALD process characteristics.

For example, in the method of forming a thin film, the deposition pressure may be 0.01 to 30 Torr, preferably 0.1 to 30 Torr, more preferably 1 to 30 Torr, most preferably 5 to 20 Torr. Within this range, a thin film having a uniform thickness may be obtained.

In the present disclosure, the deposition temperature and the deposition pressure may be temperature and pressure in a deposition chamber or temperature and pressure applied to a substrate in a deposition chamber.

The method of forming a molybdenum-based thin film may preferably include a step of increasing temperature in a chamber to a deposition temperature before introducing the film quality improver into the chamber; and/or a step of performing purging by injecting an inert gas into the chamber before introducing the film quality improver into the chamber.

In addition, as a thin film-forming apparatus capable of implementing the method of forming a molybdenum-based thin film, the present invention may include a thin film-forming apparatus including an ALD chamber, a first vaporizer for vaporizing a film quality improver, a first transfer means for transferring the vaporized film quality improver into the ALD chamber, a second vaporizer for vaporizing a thin film precursor, and a second transfer means for transferring the vaporized thin film precursor into the ALD chamber. Here, vaporizers and transfer means commonly used in the art to which the present invention pertains may be used without particular limitation.

As a specific example, the method of forming a thin film is described in detail as follows. First, a substrate on which a thin film is to be formed is placed in a deposition chamber capable of performing atomic layer deposition.

The substrate may include a semiconductor substrate such as a silicon substrate or a silicon oxide substrate.

A conductive layer or an insulating layer may be further formed on the substrate.

To deposit a thin film on the substrate placed in the deposition chamber, the film quality improver and a molybdenum precursor or a mixture of the molybdenum precursor and a non-polar solvent are prepared, respectively.

Then, the prepared film quality improver is injected into a vaporizer, converted into a vapor phase, transferred to a deposition chamber, and adsorbed on the substrate. Then, the non-adsorbed film quality improver is purged.

Next, the prepared molybdenum precursor or a mixture (composition for forming a thin film) of the molybdenum precursor and a non-polar solvent is injected into a vaporizer, converted into a vapor phase, transferred to a deposition chamber, and adsorbed on the substrate. Then, the non-adsorbed molybdenum precursor/composition for forming a thin film is purged.

In the present disclosure, the process of adsorbing the film quality improver on the substrate and performing purging to remove the non-adsorbed film quality improver; and the process of adsorbing the molybdenum precursor on the substrate and performing purging to remove the non-adsorbed molybdenum precursor may be performed by changing the order thereof as needed.

In the present disclosure, when the film quality improver and the molybdenum precursor (composition for forming a thin film) are transferred to a deposition chamber, a vapor flow control (VFC) method using a mass flow control (MFC) method, or a liquid delivery system (LDS) using a liquid mass flow control (LMFC) method may be used. Preferably, the LDS method is used.

In this case, one selected from argon (Ar), nitrogen (N₂), and helium (He) or a mixed gas of two or more thereof may be used as a transport gas or a diluent gas for moving the film quality improver or the molybdenum precursor onto the substrate, but the present invention is not limited thereto.

In the present disclosure, for example, an inert gas may be used as the purge gas, and the transport gas or the dilution gas may be preferably used as the purge gas.

Next, a reaction gas is supplied. Reaction gases commonly used in the art to which the present invention pertains may be used as the reaction gas of the present invention without particular limitation. Preferably, the reaction gas may include a reducing agent, a nitrifying agent, or an oxidizing agent. A nitride film is formed by reacting the nitrifying agent with the molybdenum precursor adsorbed on the substrate, a metal thin film is formed by reacting the reducing agent with the molybdenum precursor adsorbed on the substrate, and an oxide film is formed by reacting the oxidizing agent with the molybdenum precursor adsorbed on the substrate.

Preferably, the nitrifying agent may be a nitrogen gas (N₂), a hydrazine gas (N₂H₄), or a mixture of a nitrogen gas and a hydrogen gas, the oxidizing agent may be an oxygen gas (O₂), an ozone gas, or a mixture of an oxygen gas and an ozone gas, and the reducing agent may be a hydrogen gas (H₂).

For example, in the method of forming a thin film, the deposition temperature may be 50 to 800° C., preferably 200 to 700° C., as a specific example, 250 to 500° C., 250 to 450° C., 380 to 420° C., or 400 to 450° C. Within this range, thin film resistivity and step coverage may be greatly improved.

Next, the unreacted residual reaction gas is purged using an inert gas. Accordingly, in addition to the excess reaction gas, produced by-products may also be removed.

As described above, in the method of forming a molybdenum-based thin film, for example, the step of shielding a film quality improver on a substrate, the step of purging the non-adsorbed film quality improver, the step of adsorbing a molybdenum precursor/composition for forming a thin film on the substrate, the step of purging the non-adsorbed molybdenum precursor/composition for forming a thin film, the step of supplying a reaction gas, and the step of purging the remaining reaction gas may be set as a unit cycle. The unit cycle may be repeatedly performed to form a thin film having a desired thickness.

As another example, in the method of forming a molybdenum-based thin film, the step of adsorbing a molybdenum precursor/composition for forming a thin film on a substrate, the step of purging the non-adsorbed molybdenum precursor/composition for forming a thin film, the step of adsorbing a film quality improver on the substrate, the step of purging the non-adsorbed film quality improver, the step of supplying a reaction gas, and the step of purging the remaining reaction gas may be set as a unit cycle. The unit cycle may be repeatedly performed to form a thin film having a desired thickness.

For example, the unit cycle may be performed 1 to 99,999 times, preferably 10 to 1,000 times, more preferably 50 to 5,000 times, still more preferably 100 to 2,000 times. Within this range, desired thin film properties may be effectively expressed.

In addition, the present invention provides a semiconductor substrate. The semiconductor substrate is fabricated using the method of forming a molybdenum-based thin film of the present invention. In this case, the step coverage, thickness uniformity, density, and electrical properties of a thin film may be excellent.

Preferably, the formed thin film has a thickness of 20 nm or less, a resistivity value of 0.1 to 400 μΩ·cm based on a thin film thickness of 10 nm, a halogen content of 10,000 ppm or less, and a step coverage of 90% or more. Within this range, the thin film has excellent performance as a diffusion barrier and may reduce corrosion of metal wiring materials, but the present invention is not limited thereto.

For example, the thin film may have a thickness of preferably 1 to 20 nm, more preferably 3 to 25 nm, still more preferably 5 to 20 nm. Within this range, thin film properties may be excellent.

For example, based on a thin film thickness of 10 nm, the thin film may have a resistivity value of 0.1 to 400 μΩ·cm, preferably 15 to 300 μΩ·cm, more preferably 20 to 290 μΩ·cm, still more preferably 25 to 280 μΩ·cm. Within this range, thin film properties may be excellent.

The thin film may have a halogen content of preferably 10,000 ppm or less or 1 to 9,000 ppm, more preferably 5 to 8,500 ppm, still more preferably 100 to 1,000 ppm. Within this range, thin film properties may be excellent, and the growth rate of a thin film may be reduced. Here, for example, the halogen remaining in the thin film may be Cl₂, Cl, or Cl⁻. As the amount of halogen remaining in the thin film decreases, film quality increases.

For example, the thin film may have a step coverage of 90% or more, preferably 92% or more, more preferably 95% or more. Within this range, even a thin film with a complicated structure may be easily deposited on a substrate, which has the advantage of being applicable to next-generation semiconductor devices.

In the present invention, unless otherwise specified, step coverage may be calculated in a manner known in the art. For example, the thin film thickness deposited on the top (top deposition thickness) and the thin film thickness deposited on the side (side deposition thickness) are measured, and a value obtained by dividing the top deposition thickness by the side deposition thickness is expressed as a percentage. At this time, the percentage value is the step coverage.

For example, the thin film may have a resistivity value of 1500 μΩ·cm or less, preferably 1400 μΩ·cm or less, more preferably 1300 μΩ·cm or less. As the resistivity value decreases, the properties of the thin film may be improved. Within this range, the electrical properties required for a thin film with a complicated structure may be provided, so the thin film may be applied to next-generation semiconductor devices.

For example, the formed thin film may include a molybdenum film, a molybdenum oxide film, or a molybdenum nitride film. In this case, the thin film may be usefully used as a diffusion barrier or electrode of a semiconductor device.

For example, when necessary, the thin film may have a multilayer structure consisting of two or three layers. As a specific example, the multilayer structure consisting of two layers may be a lower layer-middle layer structure, and the multilayer structure consisting of three layers may be a lower layer-middle layer-upper layer structure.

For example, the lower layer may be composed of one or more selected from the group consisting of Si, SiO₂, MgO, Al₂O₃, CaO, ZrSiO₄, ZrO₂, HfSiO₄, Y₂O₃, HfO₂, LaLuO₂, Si₃N₄, SrO, La₂O₃, Ta₂O₅, BaO, and TiO₂.

For example, the middle layer may be composed of TiₓN_{y}, preferably TN.

For example, the upper layer may be composed of one or more selected from the group consisting of W and Mo.

Hereinafter, the present invention will be described in more detail with reference to the following preferred examples. However, these examples are provided for illustrative purposes only and should not be construed as limiting the scope and spirit of the present invention. In addition, it will be apparent to those skilled in the art that various changes and modifications may be made without departing from the spirit and scope of the present invention, and such changes and modifications are also within the scope of the appended claims.

### EXAMPLES

### Examples 1 to 5, Comparative Examples 1 to 3, Reference Example 1

The combinations shown in Table 1 below were selected as the film quality improver and molybdenum precursor to be used in the experiment.

TABLE 1

| Molybdenum precursor | Film quality improver |
|---|---|
| MoO₂Cl₂ (Compound | Tert-butyl iodide |
| represented by Chemical | |
| Formula 34) | |
| MoO₂Cl₂ | Diiodomethane |
| MoO₂Cl₂ | 1-iodobutane |
| MoO₂Cl₂ | 2-iodobutane |
| MoO₂Cl₂ | Cyclohexyl iodide |
| MoO₂Cl₂ | 2-iodo-2-methyl propane |
| MoO₂Cl₂ | 1-bromo-1-methyl cyclohexane |
| MoO₂Cl₂ | 3-iodo-2,4-dimethylpentane |
| MoO₂Cl₂ | 3-ethyl-2-pentene |
| MoO₂Cl₂ | 1,2,3-trichloropropane |

### Example 1

Among the compounds listed in Table 1, tert-butyl iodide as a film quality improver and MoO₂Cl₂, a compound represented by Chemical Formula 34 as a molybdenum precursor, were prepared. The prepared film quality improver and thin film precursor compound were each placed in a canister and supplied to a vaporizer heated to 150° C. at a flow rate of 0.05 g/min using a liquid mass flow controller (LMFC) at room temperature.

The film quality improver and thin film precursor compound, which had been vaporized in a vaporizer, each were added to a deposition chamber loaded with an Si substrate for 1 second at an input ratio of 1:1, and then argon gas was supplied at 5000 sccm for 2 seconds for argon purging. At this time, the pressure within the reaction chamber was controlled at 2.5 Torr.

Next, 1000 sccm of ammonia as a reactive gas was introduced into the reaction chamber for 3 seconds, and then argon purging was performed for 3 seconds. At this time, the substrate on which a metal thin film was to be formed was heated to the temperature of 380° C. shown in Table 2 below. This process was repeated 200 to 400 times to form a MoN thin film, a self-limiting atomic layer with a thickness of 10 nm.

### Example 2

Among the compounds listed in Table 1, tert-butyl iodide as a film quality improver and MoO₂Cl₂, a compound represented by Chemical Formula 34 as a molybdenum precursor, were prepared. The prepared film quality improver and thin film precursor compound were each placed in a canister and supplied to a vaporizer heated to 150° C. at a flow rate of 0.05 g/min using a liquid mass flow controller (LMFC) at room temperature.

The film quality improver and thin film precursor compound, which had been vaporized in a vaporizer, each were added to a deposition chamber loaded with an Si substrate for 1 second at an input ratio of 1:1, and then argon gas was supplied at 5000 sccm for 2 seconds for argon purging. At this time, the pressure within the reaction chamber was controlled at 2.5 Torr.

Next, 1000 sccm of ammonia as a reactive gas was introduced into the reaction chamber for 3 seconds, and then argon purging was performed for 3 seconds. At this time, the substrate on which a metal thin film was to be formed was heated to the temperature of 400° C. shown in Table 2 below. This process was repeated 200 to 400 times to form a MoN thin film, a self-limiting atomic layer with a thickness of 10 nm.

### Example 3

Among the compounds listed in Table 1, tert-butyl iodide as a film quality improver and MoO₂Cl₂, a compound represented by Chemical Formula 34 as a molybdenum precursor, were prepared. The prepared film quality improver and thin film precursor compound were each placed in a canister and supplied to a vaporizer heated to 150° C. at a flow rate of 0.05 g/min using a liquid mass flow controller (LMFC) at room temperature.

The film quality improver and thin film precursor compound, which had been vaporized in a vaporizer, each were added to a deposition chamber loaded with an Si substrate for 1 second at an input ratio of 1:1, and then argon gas was supplied at 5000 sccm for 2 seconds for argon purging. At this time, the pressure within the reaction chamber was controlled at 2.5 Torr.

Next, 1000 sccm of ammonia as a reactive gas was introduced into the reaction chamber for 3 seconds, and then argon purging was performed for 3 seconds. At this time, the substrate on which a metal thin film was to be formed was heated to the temperature of 420° C. shown in Table 2 below. This process was repeated 200 to 400 times to form a MoN thin film, a self-limiting atomic layer with a thickness of 10 nm.

### Comparative Examples 1 to 3

The same process as in Examples 1 to 3 was performed except that the film quality improver was not included.

As a result, an MoN thin film, a self-limiting atomic layer with a thickness of 10 nm, was formed.

### Example 4

The same process as in Example 1 was performed except that the film quality improver and thin film precursor compound, which had been vaporized in a vaporizer, were sequentially added to a deposition chamber loaded with a substrate for 1 second at an input ratio of 1:1, and then argon gas was supplied at 5000 sccm for 2 seconds for argon purging.

Specifically, the film quality improver, which had been vaporized in a vaporizer, was introduced into the deposition chamber loaded with the substrate for 1 second, and then argon gas was supplied at 5000 sccm for 2 seconds to perform argon purging. Then, the molybdenum precursor, which had been vaporized in a vaporizer, was introduced into the deposition chamber loaded with the substrate for 1 second, and then argon gas was supplied at 5000 sccm for 2 seconds to perform argon purging.

As a result, an MoN thin film, a self-limiting atomic layer with a thickness of 10 nm, was formed by repeating 200 to 400 times.

### Example 5

The same process as in Example 1 was performed except that the thin film precursor and film quality improver, which had been vaporized in a vaporizer, were sequentially added to a deposition chamber loaded with a substrate for 1 second at an input ratio of 1:1, and then argon gas was supplied at 5000 sccm for 2 seconds for argon purging.

Specifically, the molybdenum precursor, which had been vaporized in a vaporizer, was introduced into the deposition chamber loaded with the substrate for 1 second, and then argon gas was supplied at 5000 sccm for 2 seconds to perform argon purging. Then, the film quality improver, which had been vaporized in a vaporizer, was introduced into the deposition chamber loaded with the substrate for 1 second, and then argon gas was supplied at 5000 sccm for 2 seconds to perform argon purging.

As a result, an MoN thin film, a self-limiting atomic layer with a thickness of 10 nm, was formed by repeating 200 to 400 times.

### Reference Example 1

The same process as in Example 1 was performed except that, instead of tert-butyl iodide, iodobutane was used as the film quality improver.

As a result, an MoN thin film, a self-limiting atomic layer with a thickness of 10 nm, was formed.

### Experimental Examples

### 1) Deposition Evaluation (Deposition Rate Per Cycle, GPC)

The thickness of the manufactured thin film was measured using an ellipsometer, which is used to measure optical properties such as the thickness of a thin film or refractive index using the polarization characteristics of light. The deposition rate was calculated by dividing the measured thin film thickness by the number of cycles to calculate the thickness of the thin film deposited per cycle, and the results are shown in Table 2 below.

### 2) Evaluation of Thin Film Resistance (Resistivity)

The surface resistance of the formed thin film was measured using the four-point probe method to obtain sheet resistance, and then the resistivity value (μΩ·cm) was calculated from the thickness value of the thin film, and the results are shown in Table 2 below.

TABLE 2

| | Film quality | | GPC | |
|---|---|---|---|---|
| | improver | Deposition | deposition | |
| | (Injection | temperature | rate | Resistivity |
| Classification | type) | (° C.) | (Å/cycle) | (μQ · cm) |
| Example 1 | Tert-butyl | 380 | 0.952 | 1884 |
| | iodide | | | |
| | (Mixing | | | |
| | injection) | | | |
| Example 2 | Tert-butyl | 400 | 0.946 | 1280 |
| | iodide | | | |
| | (Mixing | | | |
| | injection) | | | |
| Example 3 | Tert-butyl | 420 | 1.156 | 919 |
| | iodide | | | |
| | (Mixing | | | |
| | injection) | | | |
| Comparative | — | 380 | 0.566 | 2350 |
| Example 1 | | | | |
| Comparative | — | 400 | 0.704 | 2300 |
| Example 2 | | | | |
| Comparative | — | 420 | 0.781 | 1697 |
| Example 3 | | | | |

As shown in Table 2, in the case of using the tert-butyl iodide of the present invention as the film quality improver and the thin film precursor compound in combination (Examples 1 to 3), compared to the case of not using the film quality improver (Comparative Examples 1 to 3), equivalent or similar deposition rates were provided. In addition, the resistivity was reduced to 919 to 1884 μΩ·cm. These results showed that the electrical properties were improved by appropriately controlling the thin film growth rate.

### 3) Impurity Reduction Characteristics

X-ray photoelectron spectroscopy (XPS) was performed on titanium (Ti), nitrogen (N), chlorine (Cl), carbon (C), and oxygen (O) to compare the impurities, i.e., process by-products reduction characteristics, of the manufactured 10 nm thick thin film, and the results are shown in Table 3 below.

TABLE 3

| | Film quality | Impurities (%) | | | | |
|---|---|---|---|---|---|---|
| Classification | improver | Ti | N | Cl | C | O |
| Comparative | X | 38.07 | 38.01 | 0.10 | 0.11 | 23.71 |
| Example 1 | | | | | | |
| Example 1 | Tert-butyl | 37.21 | 33.18 | 1.02 | 0.51 | 28.08 |
| | iodide | | | | | |
| Reference | Iodobutane | 39.18 | 39.18 | 0.05 | 0.01 | 21.63 |
| Example 1 | | | | | | |

As shown in Table 3, the case of Example 1 using the film quality improver according to the present invention and the thin film precursor compound at the same time exhibited a level similar to that of Comparative Example 1 not using the film quality improver. In addition, compared to Reference Example 1 using another film quality improver, the intensities of Cl and C decreased to 0.01%, indicating that impurity reduction characteristics were excellent. In particular, in the case of Comparative Example 1, since no film quality improver was added, in theory, no carbon should be detected. However, carbon, presumed to originate from trace amounts of CO and/or CO₂ contained in the thin film precursor compound, purge gas, and reaction gas, was detected. In Example 1 of the present invention, the carbon intensity decreased compared to Comparative Example 1 even though a film quality improver, which is a hydrocarbon compound, was added during thin film deposition. These results indicate that the film quality improver of the present invention has excellent impurity reduction characteristics.

In particular, in Reference Example 1, a compound with a halide-based structure was introduced, similar to the film quality improver of the present invention. However, it was confirmed that the impurities were too high compared to Example 1 and Comparative Example 1, so there was no effect of improving film quality.

In addition, to confirm the effect of each stage of injection of the film quality improver, the following experiment was additionally conducted.

### Example 6

Using MoO₂Cl₂ as a Mo precursor, ALD deposition evaluation was performed using the VFC supply method.

The canister heating temperature of MoO₂Cl₂ was 90° C., and the deposition evaluation was conducted at temperatures of 380° C., 400° C., and 420° C., respectively. The process pressure was 6 torr, and the flow rates of ammonia reaction gas and Ar purge gas were both 1000 sccm.

To confirm the effect of improving resistivity and GPC, an MoN thin film was deposited and compared.

Specifically, an experiment (post-injection) was performed in which an ALD deposition experiment was performed by injecting MoO₂Cl₂, purging with Ar, injecting tert-butyl iodide, injecting Ar, injecting NH₃ reaction gas, and then injecting Ar, and an experiment (pre-injection) was performed in which an ALD deposition experiment was performed by injecting tert-butyl iodide, injecting Ar, injecting MoO₂Cl₂, injecting Ar, injecting NH₃ reaction gas, and then injecting Ar. Then, resistivity and deposition rate were measured using the method described in the experimental example. As a control, the resistivity and deposition rate were measured for the MoN thin film produced without the addition of the film quality improver in the same manner.

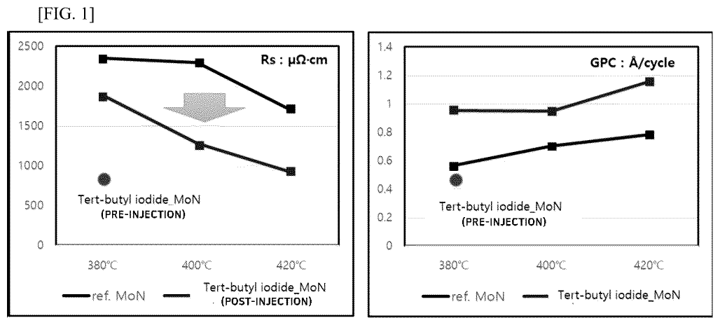

Each measurement result is shown in FIG. 1 below. FIG. 1 is a diagram comparing the results of an experiment in which the film quality improver suggested in the present invention was pre-injected and post-injected into MoO₂Cl₂ and the results of Example 6 of a control experiment in which the film quality improver was not used.

As shown in FIG. 1, the resistivity shown in the left drawing was improved for both pre- and post-injection compared to the control group. Among these results, it was confirmed that pre-injection showed the most improved results. In addition, the deposition rate shown in the drawing on the right was confirmed to show further improved results in pre-injection. Based on these results, it was confirmed that pre-injection of the film quality improver was more effective than post-injection.

1. A film quality improver for a molybdenum-based thin film, wherein the molybdenum-based thin film comprises molybdenum metal, molybdenum oxide, or molybdenum nitride on a substrate, and
the film quality improver is a saturated compound represented by Chemical Formula 1 below. 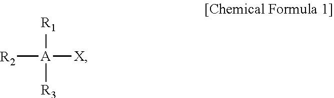
wherein A is carbon (C) or silicon (Si);
X is fluorine (F), chlorine (Cl), bromine (Br), or iodine (I);
R₁ and R₃ are independently hydrogen, an alkyl group having 1 to 5 carbon atoms, fluorine (F), chlorine (Cl), bromine (Br), or iodine (I);
R₂ independently has hydrogen, an alkyl group having 1 to 5 carbon atoms, fluorine (F), chlorine (Cl), bromine (Br), iodine (I), or a functional group of formula BR₄R₅R₆;
B is carbon or silicon; and
R₄, R₅, and R₆ are independently hydrogen, an alkyl group having 1 to 5 carbon atoms, fluorine (F), chlorine (Cl), bromine (Br), or iodine (I).

2. The film quality improver according to claim 1, wherein the film quality improver has a refractive index (a) of 1.38 to 1.72, and a value (b/a) obtained by dividing vapor pressure (25° C., mmHg, b) by the refractive index (a) is 0.003 to 0.043.

3. The film quality improver according to claim 1, wherein, when comparing ¹H-NMR spectrum for the film quality improver and ¹H-NMR spectrum measured after mixing the film quality improver and a molybdenum precursor in a molar ratio of 1:1 and pressing, the film quality improver is a compound in which an integral value of a newly created peak is less than 0.1%, and the molybdenum precursor is solid or liquid under conditions of 20° C. and 1 bar.

4. The film quality improver according to claim 1, wherein the film quality improver does not remain in the molybdenum-based thin film.

5. The film quality improver according to claim 1, wherein the molybdenum-based thin film is used as a diffusion barrier or an electrode.

6-13. (canceled)
